(19) United States
(12) Patent Application Publication
(10) Pub. No.: US 2008/0026505 A1
(43) Pub. Date: Jan. 31, 2008

(54) Electronic packages with roughened wetting and non-wetting zones

(76) Inventor: Nirupama Chakrapani, Chandler, AZ (US)

Correspondence Address: TROP PRUNER & HU, PC, 1616 S. VOSS ROAD, SUITE 750, HOUSTON, TX, 77057-2631, US

(21) Appl. No.: 11/494,858

(22) Filed: Jul. 28, 2006

(51) Int. Cl. H01L 21/00

(52) U.S. Cl. 438/106

(57) ABSTRACT

The flow of polymer formulations in in integrated circuit packages can be controlled by altering the roughness and surface chemistry of package surfaces. The surface roughness can be altered by forming protrusions having a dimension less than 500 nanometers and their chemistry can be controlled by chemical or plasma treatment. Hydrophilic surfaces may be made hemi-wicking and hydrophobic surfaces may be super-hydrophobic by particles of the same general characteristics.

### BACKGROUND

This relates to the fabrication of integrated circuit packages for holding integrated circuit chips.

In some integrated circuit packages, a substrate may mount one or more integrated circuit chips. Between the chip and the substrate may be an underfill material. Advantageously, this material fills up the region between the chip and the substrate, but does not extend outwardly by an excessive amount therefrom. Doing so may adversely affect the operation of the packaged part. For example, when the underfill material is injected between the integrated circuit and the substrate, it may tend to flow outwardly, creating what is called a tongue of material that extends out from under the integrated circuit die.

Underfilling may be done by capillary flow. In order to achieve high throughput times, the underfill may be made with a very low viscosity and good wettability to the substrate solder resist. Moreover, the underfill may be dispensed at elevated temperatures. The result of all these factors is that a tongue of underfill is left on the underfill dispense side of the package. The tongue effectively increases the footprint of the package.

### BRIEF DESCRIPTION OF THE DRAWINGS

FIG. 1 is an enlarged, cross-sectional view of a package in accordance with one embodiment of the present invention;

FIG. 2 is a greatly enlarged, cross-sectional view of a portion of the upper surface of the package substrate shown in FIG. 1; and

FIG. 3 is an enlarged, cross-sectional view of another embodiment.

### DETAILED DESCRIPTION

In some applications in semiconductor integrated circuit packaging, it is desirable to have a substrate that has regions which are both wetting and non-wetting. It would be even more desirable that the substrate have regions that are super wettable and super unwettable. In other words, the same substrates may have surface regions that are super-hydrophobic and hemi-wicking and hydrophilic. As a result, underfill and other fluxes may be closely controlled to spread out in limited regions on the substrate.

In some embodiments of the present invention, fine particle coatings may be applied across a substrate surface. The coatings may, for example, be silicon nanorods which are grown on the substrate and extend to a height of up to 500 nanometers. If the substrate upper surface is relatively hydrophilic, then the presence of the surface roughening nanoparticles serves to greatly increase the hydrophilic nature of the surface in what may be called hemi-wicking. Conversely, if the same surface is hydrophobic, it can result in super-hydrophobic or extreme non-wetting surface.

Generally, a high energy (for example hydrophilic) surface has a surface energy greater than or equal to 70 mN/m. A low energy (hydrophobic) surface has a surface energy less than or equal to 20 mN/m.

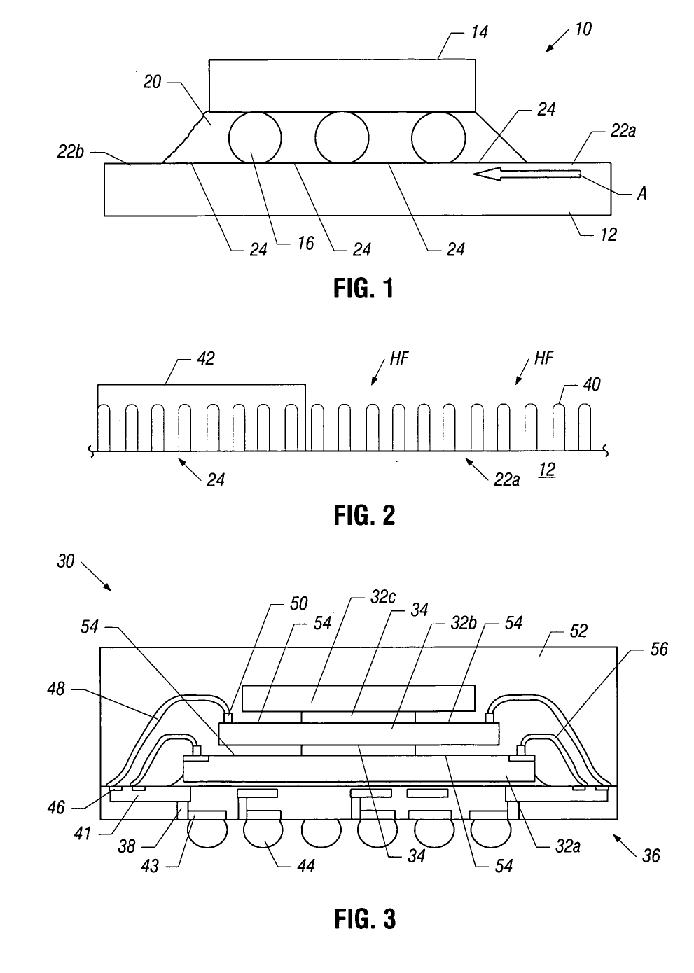

Referring to FIG. 1, a substrate 12 has an integrated circuit die 14 mounted thereon in a flip chip arrangement using solder balls 16 to electrically and mechanically connect the die 14 to the substrate 12. The substrate 12 may have interconnections which provide signals to the die 14 and transfer signals from the die 14 to external devices.

The upper surface of the substrate 12 may have peripheral regions 22 (e.g. 22a and 22b) which may be highly non-wetting and hydrophobic. Conversely, the regions 24 underneath the die and to a slight degree up from under the die may be very hydrophilic and hemi-wicking. Thus, the underfill material 20, once injected in the direction A, for example using capillary forces, moves away from the hydrophobic surfaces 22a and 22b and spreads on the hydrophilic surfaces 24. Because the surfaces 22 and 24 are hemi-wicking, the normal wetting and non-wetting effects are enhanced. As a result, the tendency of the underfill 20 to form a tongue by extending outwardly in a direction opposite to the arrow A is reduced. This may achieve a smaller package footprint, in some cases, since substrate surface is not consumed by an underfill tongue.

Referring to FIG. 3, as still another example, the package 30 may include a substrate 36 which includes interconnects 44 such as solder balls. Electrical vertical vias 38 may be found within the substrate 36 which connect to horizontal metallizations 41 to distribute signals between the external world coupled by the interconnects 44 and the integrated circuit die 32a, 32b, and 32c within the package 30. An encapsulant 52 may surround the die 32a, 32b, and 32c.

The die 32a may be coupled by a wire bond 56 to a pad 46 on the substrate 36. The pad 46 may be coupled by the horizontal metallization 41 to the vertical via 38 and, ultimately, down to a pad 43 that is coupled to an interconnect 44. In this way, communications may be had between external components and the die 32a. Likewise, the wire bond 48 may connect to the die 32b via contact 50. Connections to the die 32c may be provided in a variety of different ways. The die 32c may be coupled to the die 32b by a die attach adhesive layer 34. Likewise, the die 32b may be coupled by a die attach adhesive layer 34 to the die 32a. However, other techniques for securing the dice together may also be utilized.

In this case, it may be desirable to prevent the adhesive used for the die attach 34 from bleeding out. If the die attach bleeds out, it may foul the regions intended for wire bond contacts. Thus, the surfaces 54 may be treated to be highly non-wetting or super-hydrophobic. These surfaces may be provided on both the die 32b upper surface and the die 32c upper surface.

Referring back to FIG. 2, in some embodiments of the present invention, the fine particles 40 may be grown or deposited via a liquid coating on the substrate 12. The particles 40 may, for example, be nanorods, spherical particles, tetrapods etc. They could be made of materials including but not limited to silica, alumina, zirconia, silicon, carbon etc. However, other components and shapes may be utilized. Generally, it is desirable that these particles 40 have a height above the surface of the substrate 12 of from 5 to 500 nanometers. This is effective to enhance the hydrophobic or hydrophilic nature of the resulting surface.

When it is desired to form both hydrophilic and hydrophobic structures on the same surface, the same fine elements may be formed. That is, particles 40 of comparable composition and size may be formed across the surfaces that are supposed to be ultimately super-hydrophobic or hemi-wicking and hydrophilic. Then, the surfaces that are to be hydrophobic may be exposed to treatments such as, but not limited to, fluorination or alkylation and hydrofluoric acid treatment. The surfaces that will remain hydrophilic may be masked with a suitable, removable mask 42.

Other hydrophobic treatments may also be used. For example, fluorinated silanes are hydrophobic. They can easily be functionalized to surfaces via alcohol groups or with plasma treatment prior to functionalization. For example, a constituent R₃—Si—OH, together with HO-substrate solder resist yields R₃—Si—O-substrate solder resist. The constituent R may be, but need not be limited to, an alkane, vinyl, or fluorine. Alternatively, different treatments may be used to create a hydrophilic surface. For example, amine terminated silanes are hydrophilic. In addition, alkane silanes are hydrophobic. Moreover, long chain alkanes self-assemble into monolayers, rendering very high density silanes on the surface. Such monolayers may be deposited by a solvent route or by vapor deposition. In addition, hydroxyl groups on a solder resist surface can link silanols with appropriate moieties to render them non-wetting to underfills. Specific regions of a surface may be patterned with a silane treatment to obtain regions that are non-wetting to underfill.

A silane coating may include, but is not limited to, dichlorodimethylsilane, dichlorodiethylsilane, bisdimethylamino dimethylsilane, dimethylamino trimethylsilane, hexamethyldisilazane.

In some embodiments of the present invention, the structure may be dipped to apply the hydrofluoric acid. The hydrofluoric acid may be 48 to 51 percent and the exposure may be for one minute in some embodiments of the present invention.

The growth of the particles 40 in the form of nanorods may be done using glancing angle deposition techniques. Glancing angle deposition involves physical vapor deposition on a substrate that is rotated in two different directions. A glancing angle is formed between the input vapor source and the surface on which the nanorods are intended to be grown. In some cases, the angle may be from 70 to 90 degrees. A deposition rate of 0.2 nMs⁻¹ and a rotation speed of 0.05 revs⁻¹ may be used. An electron beam evaporator with a quartz crystal thickness monitor may be used to detect the film thickness.

Thus, surfaces can be selectively made highly hydrophilic or highly hydrophobic. Hydrophobic regions may be effective keep out zones to prevent incursion of fluxes, underfills, or encapsulants, to mention a few examples. Conversely, the spreading of underfills and molding compounds through narrow channels over ever-shrinking packages may be improved by creating a hemi-wicking surface.

Nanoparticles generally have at least one of their dimensions less than 100 nanometers. However, as used herein, a fine particle is a particle with a size up to 500 nanometers. Suitable shapes include, but are not limited, spheres, tetrapods, rods, tubes, and platelets, to mention a few examples. Suitable materials include, but are not limited to, silica, alumina, titania, zirconia, and carbon.

Instead of growing the particles, deposited particles may be utilized. In one embodiment, particles, such as microspheres, of at least two different sizes are mixed and then deposited. The particles may be secured by an adhesive coating, but other techniques may be used as well.

In other embodiments, the desired degree of surface roughness may be achieved by damaging or denting the surface to create protrusions on the order of 5 to 500 nanometers. This may be achieved by sputtering or ion bombardment, as two examples.

References throughout this specification to “one embodiment” or “an embodiment” mean that a particular feature, structure, or characteristic described in connection with the embodiment is included in at least one implementation encompassed within the present invention. Thus, appearances of the phrase “one embodiment” or “in an embodiment” are not necessarily referring to the same embodiment. Furthermore, the particular features, structures, or characteristics may be instituted in other suitable forms other than the particular embodiment illustrated and all such forms may be encompassed within the claims of the present application.

While the present invention has been described with respect to a limited number of embodiments, those skilled in the art will appreciate numerous modifications and variations therefrom. It is intended that the appended claims cover all such modifications and variations as fall within the true spirit and scope of this present invention.

What is claimed is:

1. A method comprising:
forming a semiconductor integrated circuit package surface;
forming protrusions on said surface having a dimension less than 500 nanometers; and
applying a liquid to said package surface.

2. The method of claim 1 including forming said protrusions on said surface in two different regions such that one region is hydrophobic and the other region is hydrophilic.

3. The method of claim 2 including forming a semiconductor integrated package surface in the form of a package substrate.

4. The method of claim 3 including forming said protrusions of substantially similar dimensions.

5. The method of claim 1 including forming protrusions by bombarding the surface.

6. The method of claim 5 wherein applying a liquid includes providing a die over said substrate, and injecting underfill material between said die and said substrate.

7. The method of claim 6 including defining a keep out zone on said substrate using hydrophobic particles around said die and providing a region of hydrophilic particles between said die and said substrate.

8. The method of claim 1 including forming said surface of an integrated circuit die and treating said protrusions so that said protrusions are hydrophobic in one area and hydrophilic in another.

9. The method of claim 8 including providing a die attach to said surface such that said hydrophobic protrusions reduce bleeding out of the die attach material.

10. The method of claim 1 including coating said protrusions with a silane.

11. An integrated circuit package comprising:
a package surface;
protrusions formed on said surface having a dimension less than 500 nanometers; and
a liquid applied over said protrusions.

12. The package of claim 11 wherein said protrusions are hydrophobic.

13. The package of claim 11 wherein said protrusions are hydrophilic.

14. The package of claim 11 wherein some of those protrusions are hydrophilic and some of said particles are hydrophobic.

15. The package of claim 11 wherein said liquid is underfill.

16. The package of claim 11 wherein said liquid is die attach.

17. The package of claim 11 wherein said surface is a die surface.

18. The package of claim 11 wherein said surface is a package substrate surface.

19. The package of claim 18 wherein hydrophilic protrusions are formed on said substrate, a die positioned over said substrate, said hydrophobic protrusions being formed on said substrate around said die, the surface of said substrate under said die having protrusions formed thereon that are hydrophilic and solder balls being provided between said die and said substrate.

20. The package of claim 11 wherein said surface is a die surface and a die attach is attached to said die surface, the region contacting said die attach being hydrophilic and a region around said die attach being hydrophobic.

21. The package of claim 11 wherein said protrusions are silane coated.

22. An integrated circuit package comprising:
a package surface having protrusions on said surface having a dimension less than 500 nanometers; and
said surface having a surface energy of greater than or equal to 70 mN/m or less than or equal to 20 mN/m.

23. The package of claim 22 wherein said surface includes both hydrophilic and hydrophobic regions.

24. The package of claim 22 wherein said surface is a die surface.

25. The package of claim 22 wherein said surface is a substrate surface.

26. The package of claim 22 wherein said surface is partially covered with underfill, a die being positioned to sandwich the underfill between said die and said surface.

27. The package of claim 22 including a substrate and a die stacked on said substrate, die attach being positioned between said substrate and said die, said die attach being surrounded by a region of said surface that is hydrophobic and said die contacting a hydrophilic region of said surface.

28. The package of claim 22 wherein said protrusions are silane coated.

29. The package of claim 28 wherein said silane coated protrusions are hydrophobic.

30. The package of claim 28 wherein said silane coated protrusions are hydrophilic.
